(19) United States
(12) Patent Application Publication
(10) Pub. No.: US 2025/0357125 A1
(43) Pub. Date: Nov. 20, 2025

(54) Hot Ion Implantation for Condensation Defect Reduction

(71) Applicant: Taiwan Semiconductor Manufacturing Company, Ltd., Hsin-Chu (TW)

(72) Inventors: Bau-Ming Wang, Kaohsiung City (TW); Liang-Yin Chen, Hsinchu City (TW); Chi On Chui, Hsinchu City (TW)

(21) Appl. No.: 19/280,982

(22) Filed: Jul. 25, 2025

Related U.S. Application Data
(63) Continuation of application No. 18/524,138, filed on Nov. 30, 2023.
(60) Provisional application No. 63/513,452, filed on Jul. 13, 2023.

(51) Int. Cl. H01L 21/266; H01L 21/311

(52) U.S. Cl. CPC H01L 21/266; H01L 21/31116

(57) ABSTRACT

Methods are disclosed herein for removing residual gas and/or condensation defects that may arise from etching patterning layers. An exemplary method includes forming a patterning stack over a workpiece. The method further includes, after performing a lithography process and an etching process on the patterning stack, performing a hot ion implantation process to form implanted regions in the workpiece. The hot ion implantation process is configured to remove residual gas and/or condensation defects that may arise from the etching process performed on the patterning stack. The hot ion implantation process includes a pre-heat process and an ion implantation process. A pre-heat temperature of the pre-heat process is greater than a boiling point of the condensation defects. In some embodiments, an implantation temperature of the ion implantation process is greater than the boiling point of the condensation defects.

The present application is a continuation application of U.S. patent application Ser. No. 18/524,138, filed Nov. 30, 2023, which is a non-provisional application of and claims benefit of U.S. Provisional Patent Application Ser. No. 63/513,452, filed Jul. 13, 2023, the entire disclosures of which are incorporated herein by reference.

### BACKGROUND

Patterning processes are extensively utilized in integrated circuit (IC) manufacturing, where various IC patterns are transferred to a workpiece to form an IC device. A patterning process may involve forming a patterning layer over the workpiece, forming a resist layer over the patterning layer, exposing the resist layer to patterned radiation, developing the exposed resist layer to form a patterned resist layer, etching the patterning layer, and patterning the workpiece using the etched patterning layer (e.g., by doping and/or etching portions of the workpiece exposed by the etched patterning layer). As IC technologies progress towards smaller technology nodes, etching processes that have been implemented to improve pattern profiles of the etched patterning layer have presented other challenges, such as residual gas and corresponding condensation defects that degrade patterning uniformity. Accordingly, although existing patterning processes have been generally adequate for their intended purposes, they have not been entirely satisfactory in all respects and improvements are needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method, in portion or entirety, for patterning a workpiece that reduces condensation defects, according to various aspects of the present disclosure.

FIGS. 2A-2F are cross-sectional views of a workpiece, in portion or entirety, at various stages of patterning, such as the method for patterning a workpiece that reduces condensation defects of FIG. 1, according to various aspects of the present disclosure.

FIG. 3 is a flow chart of a method, in portion or entirety, for patterning a workpiece that reduces condensation defects, according to various aspects of the present disclosure.

FIGS. 4A-4F are cross-sectional views of a workpiece, in portion or entirety, at various stages of patterning, such as the method for patterning a workpiece that reduces condensation defects of FIG. 3, according to various aspects of the present disclosure.

FIG. 5 is a flow chart of a method, in portion or entirety, for patterning a workpiece that reduces condensation defects, according to various aspects of the present disclosure.

### DETAILED DESCRIPTION

The present disclosure relates generally to methods for manufacturing integrated circuit (IC) and/or semiconductor devices, and more particularly, to patterning techniques for reducing residual gas and/or condensation defects during manufacturing.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “substantially,” “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Patterning processes are extensively utilized in integrated circuit (IC) manufacturing, where various IC patterns are transferred to a workpiece to form an IC device. A patterning process may involve forming a tri-layer patterning layer over the workpiece. The tri-layer patterning layer may include a bottom layer (e.g., including an organic material, such as a carbon-rich polymer layer), a middle layer (e.g., including an organic material, such as a silicon-rich polymer layer), and a resist layer. The patterning process may further include exposing the resist layer to patterned radiation and developing the exposed resist layer, thereby forming a patterned resist layer. The patterned resist layer may be used as a masking element to pattern the middle layer and/or the bottom layer. For example, an etching process uses the patterned resist layer as an etch mask and removes exposed portions of the middle layer and/or the bottom layer, thereby forming a patterned middle/bottom layer. The etching process transfers a resist pattern of the patterned resist layer to the middle layer and the bottom layer. The patterning process may further include using the patterned middle/bottom layer as a masking element during subsequent IC processing, such as an implantation process (e.g., to form doped regions and/or doped wells in the workpiece) or an etching process, where a pattern of the patterned middle/bottom layer (which corresponds with the resist pattern) is transferred to the workpiece.

A quality of the resist pattern impacts a quality of the IC device. As IC technologies progress towards smaller technology nodes (e.g., down to 14 nanometers, 10 nanometers, and below), dry etching processes that use CF₄-containing gases or COS-containing gases have been implemented to improve pattern profiles of the patterned middle/bottom layer. However, these dry etching processes leave residual gas, such as CF₄ (tetrafluoromethane) or COS (carbonyl sulfide), that may cause condensation defects, such as SO₃ defects, to form randomly on the patterns, such as on the patterned middle/bottom layer, when the workpiece is stored in an environment with a relatively high humidity (e.g., greater than about 30% humidity at room temperature) for a few minutes. Though micron size, condensation defects can act as a blocking material that negatively impacts the subsequent IC processing. For example, when an ion implantation process is performed on the workpiece to form doped wells therein, the condensation defects may prevent dopant from and/or reduce an amount of dopant that reaches intended areas of the workpiece, which may cause implant dose uniformity issues in the workpiece. Further, though a deionized (DI) water rinse may remove these condensation defects, the DI water may cause high aspect ratio patterns to collapse and residual gases and/or condensation defects are still difficult to remove from the high aspect ratio patterns.

To address such challenges, the present disclosure discloses a hot ion implantation process that reduces and/or eliminates condensation defects without causing pattern collapse and that may remove condensation defects from inside high aspect ratio patterns, among other advantages. For example, the hot ion implantation process removes condensation defects from the patterned middle layer and/or the patterned bottom layer, which may improve implant dose uniformity. Different embodiments disclosed herein offer different advantages and no particular advantage is necessarily required in all embodiments.

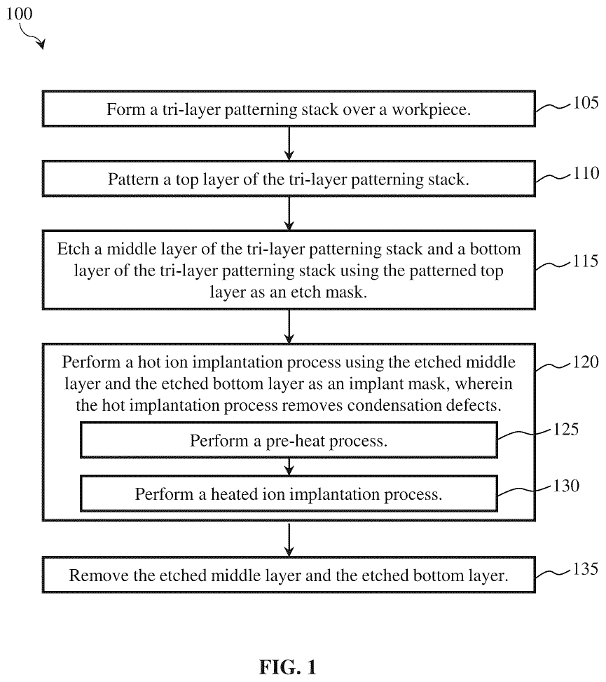

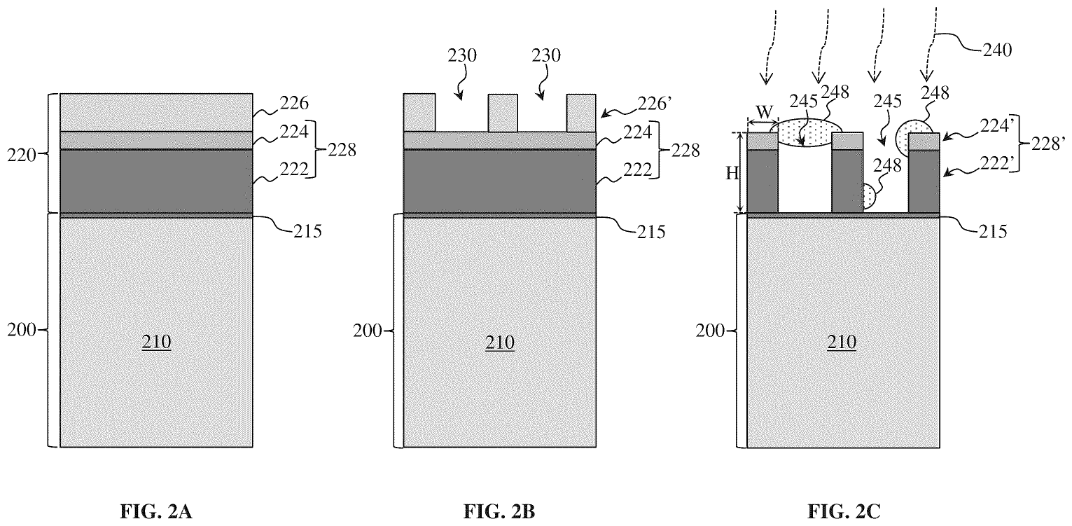

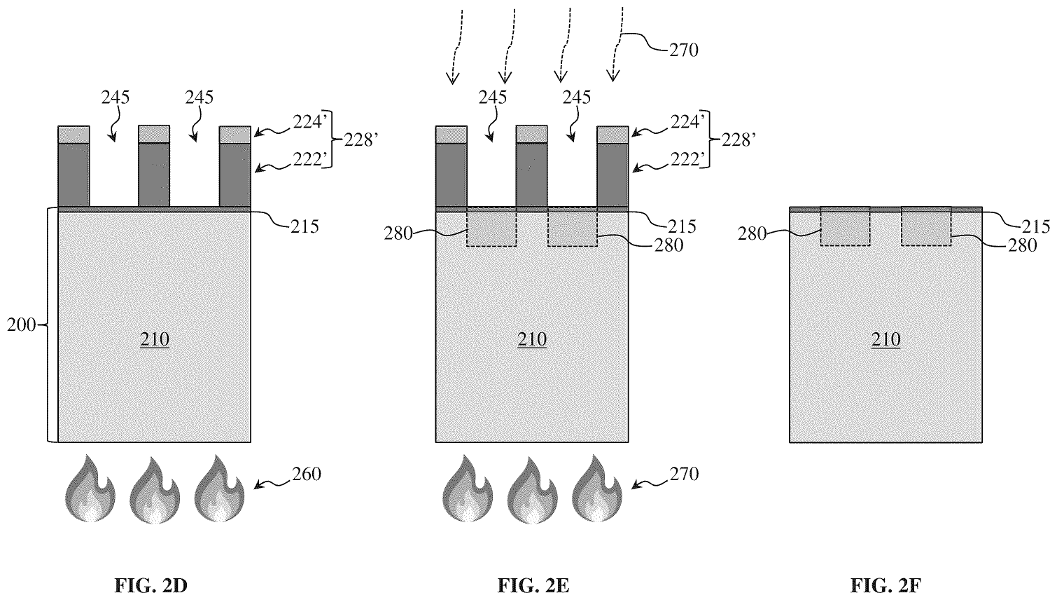

FIG. 1 is a flow chart of a method 100, in portion or entirety, for patterning a workpiece that reduces and/or removes condensation defects, according to various aspects of the present disclosure. FIGS. 2A-2F are cross-sectional views of a workpiece 200, in portion or entirety, at various stages of method 100 of FIG. 1, according to various aspects of the present disclosure. FIG. 1 and FIGS. 2A-2F are discussed concurrently herein for ease of description and understanding. FIG. 1 and FIGS. 2A-2F have been simplified for the sake of clarity to better understand the inventive concepts of the present disclosure. Additional steps can be provided before, during, and after method 100, and some of the steps described can be moved, replaced, or eliminated for additional embodiments of method 100. Additional features may be added in workpiece 200, and some of the features described below can be replaced, modified, or eliminated in other embodiments of workpiece 200.

Referring to FIG. 1 and FIG. 2A, method 100 at block 105 includes forming a tri-layer patterning stack 220 over workpiece 200. In FIG. 2A, workpiece 200 includes a substrate 210. In some embodiments, substrate 210 is a semiconductor substrate, which may include an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In some embodiments, substrate 210 is a semiconductor-on-insulator substrate, such as a silicon-on-insulator substrate, a silicon germanium-on-insulator substrate, or a germanium-on-insulator substrate. In some embodiments, an intermediate layer 215 is formed over substrate 210 before forming tri-layer patterning stack 220. In the depicted embodiment, substrate 210 is a silicon substrate, and intermediate layer 215 is an oxide layer, such as silicon oxide layer. In some embodiments, intermediate layer 215 is an adhesion layer that facilitates adhesion of tri-layer patterning stack 220 to substrate 210, and intermediate layer 215 is formed of any material that facilitates such adhesion. In some embodiments, intermediate layer 215 is omitted from workpiece 200, and tri-layer patterning stack 220 is directly on substrate 210.

Tri-layer patterning stack 220 (also referred to as a tri-layer imaging layer, a tri-layer resist, a tri-layer photoresist, etc.) includes a bottom layer 222, a middle layer 224, and a top layer 226. To achieve etch selectivity, a composition of top layer 226 is different than a composition of middle layer 224 and a composition of bottom layer 222, and the composition of middle layer 224 is different than the composition of bottom layer 222. For example, bottom layer 222, middle layer 224, and top layer 226 are formed of different materials, such that each layer of tri-layer patterning stack 220 may be etched using a corresponding etchant with no (or negligible) etching of the other layers of tri-layer patterning stack 220. In other words, bottom layer 222, middle layer 224, and top layer 226 are formed of materials having different etch rates. Accordingly, top layer 226 may serve as an etch mask for patterning middle layer 224, bottom layer 222, intermediate layer 215, substrate 210, or a combination thereof; middle layer 224 may serve as an etch mask for patterning bottom layer 222, intermediate layer 215, substrate 210, or a combination thereof; and bottom layer 222 may serve as an etch mask for patterning intermediate layer 215 and/or substrate 210. In the depicted embodiment, top layer 226 serves as an etch mask for patterning middle layer 224 and bottom layer 222, and middle layer 224 and bottom layer 222 serve as an etch mask for patterning intermediate layer 215 and/or substrate 210. In some embodiments, top layer 226 serves as an etch mask for patterning middle layer 224, middle layer 224 serves as an etch mask for patterning bottom layer 222, and bottom layer 222 serves as an etch mask for patterning intermediate layer 215 and/or substrate 210.

Bottom layer 222 is formed over intermediate layer 215 and/or substrate 210, and middle layer 224 is formed over bottom layer 222. Bottom layer 222 functions as an implant mask and/or an etch mask when an underlying layer (e.g., intermediate layer 215 and/or substrate 210) is patterned, for example, by an implantation process and/or an etching process, and middle layer 224 functions as an etch mask when bottom layer 222 is patterned, for example, by an etching process. Bottom layer 222 and middle layer 224 may also function as antireflection layers. For example, bottom layer 222 and middle layer 224 may be formed of materials and/or thicknesses that reduce reflection of radiation (e.g., light reflection) during an exposure process, such as that used to pattern top layer 226, which may enhance imaging resolution and increase imaging contrast of the exposure process. Bottom layer 222 and middle layer 224 may thus collectively be referred to as a bottom antireflective coating (BARC) 228. In some embodiments, middle layer 224 also functions as an implant mask and/or an etch mask when the underlying layer is patterned by the implantation process and/or the etching process.

Accordingly, bottom layer 222 may be formed of a first antireflective material that is resistant to an implantation process and/or an etching process performed on the underlying layer, and middle layer 224 may be formed of a second antireflective material that is resistant to an etching process performed on bottom layer 222. In the depicted embodiment, bottom layer 222 (also referred to as an underlayer) includes an organic material, and middle layer 224 includes an organic material that is different than the organic material of bottom layer 222. For example, bottom layer 222 is a carbon-rich polymer layer, and middle layer 224 is a silicon-rich polymer layer. The carbon-rich polymer layer may include carbon and hydrogen and/or oxygen, and the silicon-rich polymer layer may include silicon and carbon, hydrogen, oxygen, or a combination thereof. In some embodiments, bottom layer 222 is a CᵢHⱼOₖ layer, and middle layer 224 is an SiCₓH_{y}O_{z} layer. In some embodiments, bottom layer 222 is free of silicon. In some embodiments, each of bottom layer 222 and middle layer 224 is formed by a respective spin coating process that is, optionally, followed by a respective baking process.

Top layer 226 is formed over middle layer 224. Top layer 226 functions as a radiation sensitive layer during a lithography process. For example, top layer 226 is sensitive to radiation used during an exposure process of the lithography process, and portions of top layer 226 that are exposed to the radiation undergo a property change (e.g., from insoluble to soluble to a developer, or vice versa). Top layer 226 also functions as an etch mask when middle layer 224 is patterned by an etching process, and top layer 226 may function as an etch mask when bottom layer 222 is patterned by an etching process. Accordingly, top layer 226 includes a radiation sensitive material (e.g., a photosensitive material) that facilitates absorption of radiation and resistance to an etching process used to pattern middle layer 224 and bottom layer 222. In some embodiments, top layer 226 includes an organic material that includes a radiation sensitive component. For example, top layer 226 is a photosensitive polymer layer, which may include a photosensitive component and carbon, hydrogen, oxygen, or a combination thereof. The photosensitive polymer layer may further include other resist components that facilitate absorption of radiation and/or crosslinking reactions upon exposure to radiation, such as photoacid generator component, thermal acid generator component, photo-decomposable base component, other suitable resist component, or a combination thereof. Top layer 226 may be referred to as a resist layer, a photosensitive layer, a photoresist layer, an imaging layer, a radiation sensitive layer, or a combination thereof. In some embodiments, top layer 226 is formed by a spin coating process that is, optionally, followed by a baking process.

A thickness of middle layer 224 may be less than a thickness of bottom layer 222 and a thickness of top layer 226, and the thickness of bottom layer 222 may be greater than the thickness of top layer 226. In some embodiments, the thickness of bottom layer 222 is about 3,900 Å to about 4,100 Å (e.g., about 4,000 Å). In some embodiments, the thickness of middle layer 224 is about 700 Å to about 900 Å (e.g., about 800 Å). In some embodiments, a thickness of top layer 226 is about 2,200 Å to about 2,400 Å (e.g., about 2,300 Å). In some embodiments, a total thickness of tri-layer patterning stack 220 is about 6,800 Angstroms (Å) to about 7,300 Å (e.g., about 7,100 Å). The present disclosure contemplates bottom layer 222, middle layer 224, and top layer 226 having other thicknesses and/or other configurations of thicknesses (e.g., the thickness of top layer 226 may be greater than the thickness of bottom layer 222, etc.).

Referring to FIG. 1 and FIG. 2B, method 100 at block 110 includes patterning top layer 226 of tri-layer patterning stack 220, thereby forming a patterned top layer 226′. Patterned top layer 226′ has openings 230 therein that expose middle layer 224. Openings 230 overlap portions of substrate 210 and/or intermediate layer 215 that will be subjected to a patterning process, such as an implantation process and/or an etching process. For example, openings 230 may overlap portions of substrate 210 that correspond with source/drain regions of a semiconductor device, such as a transistor, and where lightly doped source/drain (LDD) regions and/or heavily doped source/drain (HDD) regions may be formed by an implantation process. In another example, openings 230 may overlap portions of substrate 210 that correspond with active regions of substrate 210 that will include electrically active devices, and where doped regions, such as n-wells and/or p-wells, may be formed by an implantation process.

In some embodiments, top layer 226 is patterned by a lithography process. The lithography process may include an exposure process and a development process. The exposure process may include exposing top layer 226 to patterned radiation, which may be ultraviolet (UV) radiation, deep ultraviolet (DUV) radiation, extreme ultraviolet (EUV) radiation, x-ray radiation, other suitable radiation, or a combination thereof. In some embodiments, a mask having a pattern defined therein is used to provide the patterned radiation, which may form an image of a pattern on top layer 226. The mask may block radiation, transmit radiation, reflect radiation, or a combination thereof to top layer 226 depending on a mask pattern of the mask and/or mask type (e.g., whether the mask is a binary mask, a phase shift mask, or an EUV mask). The exposure process may be performed in air, liquid (immersion lithography), or vacuum. In some embodiments, the exposure process exposes top layer 226 to charged particle radiation, such as a charged particle beam, which may be an electron beam (e-beam) and/or an ion beam. In such embodiments, the exposure process may directly modulate radiation, such as an e-beam and/or an ion beam, according to a pattern without using a mask.

Since top layer 226 is sensitive to radiation, a latent pattern is formed on top layer 226 by the exposure processes. Latent pattern generally refers to a pattern exposed on a resist layer, which becomes a physical resist pattern after the resist layer is subjected to a development process. The latent pattern may include exposed portions (e.g., those portions exposed to the radiation) and unexposed portions (e.g., those portions that are not exposed to the radiation). The exposed portions physically and/or chemically change in response to the exposure process. In some embodiments, the exposure process causes chemical reactions in the exposed portions of top layer 226 that increase solubility thereof to a developer, such that the exposed portions are soluble to the developer and the unexposed portions are insoluble to the developer. In some embodiments, the exposure process causes chemical reactions in the exposed portions of top layer 226 that decrease solubility thereof to a developer, such that the exposed portions are insoluble to the developer and the unexposed portions are soluble to the developer. In some embodiments, the lithography process includes performing a pre-exposure baking (pre-bake) process after the exposure processes. In some embodiments, the lithography process includes performing a post-exposure baking (PEB) process after the exposure processes.

The development process may dissolve exposed (or non-exposed) portions of top layer 226 depending on characteristics of top layer 226 and characteristics of a development solution used in the development process. In some embodiments, the development process is a positive tone development (PTD) process that removes exposed portions of top layer 226. For example, a PTD developer is applied to top layer 226 that dissolves the exposed portions of top layer 226 and leaves patterned top layer 226′ having openings 230 defined by unexposed portions of top layer 226. In some embodiments, the development process is a negative tone development (NTD) process that removes unexposed portions of top layer 226. For example, a NTD developer is applied to top layer 226 that dissolves the unexposed portions of top layer 226 and leaves patterned top layer 226′ having openings 230 defined by exposed portions of top layer 226. After development, patterned top layer 226′ may have a pattern (e.g., a resist pattern) that corresponds with the pattern of the mask. In some embodiments, the lithography process includes performing a rinsing process after the development process.

Referring to FIG. 1 and FIG. 2C, method 100 at block 115 includes etching middle layer 224 of tri-layer patterning stack 220 using patterned top layer 226′ as an etch mask, thereby forming a patterned, etched middle layer 224′. Method 100 at block 115 may also include etching bottom layer 222 of tri-layer patterning stack 220 using patterned top layer 226′ as an etch mask, thereby forming a patterned, etched bottom layer 222′. In FIG. 2C, an etching process 240 removes portions of middle layer 224 and portions of bottom layer 222 that are exposed by openings 230 in patterned top layer 226′, such that etched middle layer 224′ and etched bottom layer 222′ have openings 245 that extend therethrough to expose intermediate layer 215 and/or substrate 210. Openings 245 may correspond with openings 230 in patterned top layer 226′. Etched middle layer 224′ and etched bottom layer 222′ may collectively be referred to as patterned, etched BARC 228′, which have openings 245 therein that expose an underlying layer, and etching process 240 may be referred to as a BARC etch.

In the depicted embodiment, etching process 240 is a multistep process, such as a first etch that selectively removes middle layer 224 with respect to patterned top layer 226′ and/or bottom layer 222 and a second etch that selectively removes bottom layer 222 with respect to patterned top layer 226′, etched middle layer 224′, an underlying layer (e.g., intermediate layer 215 and/or substrate 210), or a combination thereof. For example, the first etch may etch middle layer 224 with no (or negligible) etching of patterned top layer 226′ and bottom layer 222, and the second etch may etch bottom layer 222 with no (or negligible) etching of patterned top layer 226′, etched middle layer 224′, intermediate layer 215, substrate 210, or a combination thereof. A first etchant of the first etch may etch middle layer 224 (e.g., a silicon-rich polymer material) at a higher rate than patterned top layer 226′ (e.g., a photosensitive material) and bottom layer 222 (e.g., a carbon-rich polymer material). A second etchant of the second etch, which is different than the first etchant, may etch bottom layer 222 (e.g., a carbon-rich polymer material) at a higher rate than patterned top layer 226′ (e.g., a photosensitive material), etched middle layer 224′ (e.g., a silicon-rich polymer material), intermediate layer 215 (e.g., silicon oxide), substrate 210 (e.g., silicon), or a combination thereof. Each of the first etch and the second etch is a dry etch, a wet etch, other suitable etch, or a combination thereof.

The first etch may be a first dry etch that exposes middle layer 224 to a fluorine-containing etch gas. The fluorine-containing etch gas may include tetrafluoromethane (CF₄) and/or other suitable fluorine-containing etch gas constituent(s) (e.g., CHF₃ and/or C₄F₈). The fluorine-containing etch gas may also include O₂, N₂, Ar, or a combination thereof. In some embodiments, the first dry etch is a fluorocarbon plasma etch, such as a CF₄ plasma etch.

The second etch may be a second dry etch that exposes bottom layer 222 to an oxygen-containing etch gas. The oxygen-containing etch gas may include O₂, carbonyl sulfide (COS), other suitable oxygen-containing etch gas constituent(s), or a combination thereof. The oxygen-containing etch gas may also include N₂, Ar, or a combination thereof. In some embodiments, the second dry etch is an oxygen plasma etch, such as an O₂/COS plasma etch. In some embodiments, the second dry etch is a multistep process, such as a first oxygen-containing dry etch and a second oxygen-containing dry etch. The first oxygen-containing dry etch may expose bottom layer 222 to a first oxygen-containing etch gas, and the second oxygen-containing dry etch may expose bottom layer 222 to a second oxygen-containing etch gas. The first oxygen-containing etch gas may include O₂ and COS, the second oxygen-containing etch gas may include O₂ and COS, and an amount of O₂ in the first oxygen-containing etch gas is different than an amount of O₂ in the second oxygen-containing etch gas. O₂ may function/act as a main etcher/remover of bottom layer 222, and COS may function/act to prevent and/or reduce necking of sidewall profiles of remaining portions of etched bottom layer 222′ and/or etched middle layer 224′, thereby improving a pattern profile of patterned BARC 228′.

After etching, etched BARC 228′ may provide an implant mask having an implant pattern, where openings 245 therein overlap and expose portions of substrate 210 and/or intermediate layer 215 that will be subjected to an implantation process to form doped regions therein. Implementing CF₄-containing etch gases and COS-containing etch gases in the first dry etch and the second dry etch, respectively, provides etched BARC 228′ with a good pattern profile (e.g., substantially vertical sidewalls, minimal necking, minimal rounding, etc.), particularly as device feature sizes shrink with scaling IC technology nodes. However, these gases may leave residual gas, such as CF₄ and/or COS, on etched BARC 228′ (i.e., the implant pattern), and the residual gas may cause condensation defects 248, such as SO₃₍ₛ₎ defects, to form randomly on etched BARC 228′. Further, storing workpiece 200 in an environment with a relatively high humidity (e.g., greater than about 30% humidity at room temperature) for a few minutes to about an hour may trigger and/or exacerbate formation of condensation defects 248. Though micron size, condensation defects 248 may act as a blocking material that negatively impacts subsequent processing. For example, when an implantation process is performed on workpiece 200 that uses etched BARC 228′ as an implant mask to form doped regions in substrate 210 and/or intermediate layer 215, condensation defects 248 may prevent dopant from reaching and/or reduce an amount of dopant reaching exposed portions of substrate 210 and/or intermediate layer 215, which may cause implant dose uniformity issues.

Though the residual gas and/or condensation defects 248 are typically and easily removed by a deionized (DI) water rinse, completely removing such residual gas and/or condensation defects from BARC patterns and/or within openings of BARC patterns is becoming more difficult for high aspect ratio BARC patterns and/or BARC patterns formed of materials having hydrophobic nature (e.g., a hydrophobic, amorphous carbon bottom layer). High aspect ratio BARC patterns generally refer to BARC patterns having a ratio of height (H) to width (W) that is greater than about 5 (i.e., height/width≥5). In some embodiments, high aspect ratio BARC patterns have a ratio of height to width is about 5 to about 7 (i.e., 7≥height/width≥5). In some instances, the DI water may cause high aspect ratio BARC patterns to collapse.

In some embodiments, to reduce the residual gas and/or condensation defects 248, an amount of O₂ is reduced to reduce formation of SO₃₍ₛ₎ on etched BARC 228′ and/or within openings 245 of etched BARC 228′. For example, during the second dry etch, various chemical reactions may occur with O₂ that produce SO₃₍ₛ₎, such as S_{(g)}+O_{2(g)}→SO_{2(g)}, SO₃₍ₛ₎ and COS_{(g)}+O_{2(g)}→SO_{2(g)}, SO₃₍ₛ₎. By breaking the second dry etch into a multistep process, an amount of O₂ may be reduced during at least one of the second dry etch steps to reduce reactions with O₂ that may result in formation of SO₃₍ₛ₎. For example, during the second dry etch, the amount of O₂ in the second oxygen-containing etch gas is less than the amount of O₂ in the first oxygen-containing etch gas. In other words, O₂ is reduced in a second step of the second dry etch (i.e., the second oxygen-containing dry etch). In some embodiments, a flow rate of O₂ of the second oxygen-containing dry etch is less than a flow rate of O₂ of the first oxygen-containing dry etch to reduce the O₂ amount. In some embodiments, a concentration of O₂ of the second oxygen-containing dry etch is less than a concentration of O₂ of the first oxygen-containing dry etch to reduce the O₂ amount. In some embodiments, the second dry etch steps (e.g., the first oxygen-containing dry etch and the second oxygen-containing dry etch) are delineated by different amounts of O₂. In some embodiments, the second dry etch steps are delineated by other process parameters, such as etch temperature, etch pressure, etch time, power, etch gasses, etc. In some embodiments, purge processes may be performed between the second dry etch steps.

After etching process 240, patterned top layer 226′ may be removed from tri-layer patterning stack 220 by a suitable process, leaving patterned, etched BARC 228′ over workpiece 200. For example, patterned top layer 226′ is removed by a resist stripping process. The resist stripping process may be a wet strip and/or a plasma ashing. In some embodiments, patterned top layer 226′ is partially removed and/or consumed during etching process 240 (i.e., etching process 240 partially removes patterned top layer 226′), and a remainder of patterned top layer 226′ is removed by a suitable process after etching process 240. In some embodiments, patterned top layer 226′ is completely removed and/or consumed during etching process 240, such that a separate process is not performed to remove patterned top layer 226′. In some embodiments, a cleaning process may be performed after etching process 240 to remove any etch residue from etched middle layer 224′ and/or etched bottom layer 222′.

Referring to FIG. 1, FIG. 2D, and FIG. 2E, method 100 at block 120 includes performing a hot ion implantation process using etched middle layer 224′ and etched bottom layer 222′ (i.e., etched BARC 228′) as an implant mask. The hot ion implantation process includes performing a pre-heat process 260 at block 125 and performing a heated ion implantation process 270 at block 130. The hot ion implantation process is configured to remove the residual gas and/or condensation defects 248 while patterning workpiece 200 (e.g., while forming implanted regions 280 therein), thereby improving patterning (e.g., implant) uniformity. The hot ion implantation process may remove the residual gas and/or condensation defects 248 without causing the implant pattern (e.g., etched BARC 228′) to collapse, and the hot ion implantation process may completely (or sufficiently) remove residual gas and/or condensation defects 248 from high aspect ratio implant patterns. The hot ion implantation process may remove the residual gas and/or condensation defects 248 without performing a rinsing process, such as a DI water rinse. In the depicted embodiment, the hot ion implantation process removes condensation defects 248 on etched middle layer 224′, on etched bottom layer 222′, from within openings 245 of etched middle layer 224′, from within openings 245 of etched bottom layer 222′, from workpiece 200, from an ambient, or a combination thereof.

In FIG. 2D, pre-heat process 260 includes heating workpiece 200 (e.g., substrate 210 thereof), heating an environment of workpiece 200 (e.g., ambient temperature of a process chamber), heating etched BARC 228′ (e.g., etched middle layer 224′ and/or etched bottom layer 222′), heating condensation defects 248, or a combination thereof to a pre-heat temperature. The pre-heat temperature is a temperature that is greater than a boiling point of condensation defects 248, such that pre-heat process 260 causes condensation defects 248 to change from a solid state (e.g., SO₃₍ₛ₎) to a gas state (e.g., SO_{3(g)}). For example, where condensation defects 248 include SO₃₍ₛ₎ and a boiling point of SO₃₍ₛ₎ is 44.9° C., the pre-heat temperature is at least 50° C. In some embodiments, the pre-heat temperature is about 50° C. to about 200° C. In some embodiments, substrate 210 is pre-heated (e.g., from its backside) to the pre-heat temperature. Pre-heat temperatures that are too low (i.e., close to or less than a boiling point of condensation defects 248), such as less than 50° C., may not cause condensation defects 248 to change states (e.g., from solid phase into gas phase), and pre-heat process 260 may not remove (or adequately remove) condensation defects 248. Pre-heat temperatures that are too high, such as greater than 200° C., may damage (e.g., burn) etched BARC 228′ (e.g., etched middle layer 224′ and/or etched bottom layer 222′ thereof), which may hinder and/or prevent effective removal thereof. The present disclosure contemplates other pre-heat temperatures depending on type of condensation defect and corresponding boiling point, composition of etched middle layer 224′, composition of etched bottom layer 222′, composition of workpiece 200, or a combination thereof. In some embodiments, pre-heat process 260 may repair crystallographic defects in substrate 210, which may improve device yield. In such embodiments, the pre-heat temperature may be tuned to a temperature that optimizes crystallographic repair and condensation defect removal.

In some embodiments, pre-heat process 260 includes exhausting condensation defects 248 in their gas state from a process chamber containing workpiece 200. In some embodiments, pre-heat process 260 includes performing a purging process that removes condensation defects 248 in their gas state from a process chamber containing workpiece 200. In some embodiments, pre-heat process 260 uses a hot plate for heating (e.g., workpiece 200 is placed on a hot plate in a process chamber). In some embodiments, pre-heat process 260 uses one or more halogen lamps for heating (e.g., condensation defects 248, etched BARC 228′, workpiece 200, or a combination thereof may be heated by light (e.g., infrared radiation) emitted from the halogen lamp(s)). In some embodiments, pre-heat process 260 uses one or more quartz tube heaters for heating.

In FIG. 2E, heated ion implantation process 270 introduces a dopant species into substrate 210 and/or intermediate layer 215, thereby forming implanted regions 280 in substrate 210 and/or intermediate layer 215. The dopant species (also referred to as an implant species and/or dopant ions) includes silicon (Si), germanium (Ge), arsenic (As), phosphorous (P), boron (B), carbon (C), argon (Ar), nitrogen (N), xenon (Xe), other suitable dopant species, or a combination thereof. In some embodiments, heated ion implantation process 270 includes ionizing a dopant source gas and bombarding substrate 210 and/or intermediate layer 215 with dopant species from the ionized dopant source gas (e.g., by accelerating selected, desired dopant species from the ionized dopant gas into substrate 210 and/or intermediate layer 215). The dopant source gas may include silane (SiH₄), boron trifluoride (BF₃), arsine (AsH₃), phosphine (PH₃), carbon monoxide (CO), argon (Ar), nitrogen (N₂), xenon-hydrogen (Xe—H₂), germanium tetrafluoride (GeF₄), other suitable dopant source gas, or a combination thereof. For example, a silicon-containing dopant source gas, such as SiH₄ gas, may be ionized to generate silicon dopant species (Si), and heated ion implantation process 270 may direct a Si ion beam onto substrate 210 and/or intermediate layer 215 to implant semiconductor dopant species (e.g., Si). In another example, an argon-containing dopant source gas, such as Ar, may be ionized to generate argon dopant species (Ar), and heated ion implantation process 270 may direct an Ar ion beam onto substrate 210 and/or intermediate layer 215 to implant inert gas species (e.g., Ar).

Heated ion implantation process 270 includes heating workpiece 200 (e.g., substrate 210 thereof), heating an environment of workpiece 200 (e.g., ambient temperature of a process chamber), heating etched BARC 228′ (e.g., etched middle layer 224′ and/or etched bottom layer 222′), heating condensation defects 248, or a combination thereof to an implantation temperature. The implantation temperature is a temperature that is greater than a boiling point of condensation defects 248, such that heated ion implantation process 270 causes condensation defects 248 to change from a solid state (e.g., SO₃₍ₛ₎) to a gas state (e.g., SO_{3(g)}). For example, where condensation defects 248 include SO₃₍ₛ₎ and a boiling point of SO₃₍ₛ₎ is 44.9° C., the implantation temperature is at least 50° C. In some embodiments, the implantation temperature is about 50° C. to about 200° C. In some embodiments, substrate 210 is heated (e.g., from its backside) to the implantation temperature. Implantation temperatures that are too low (i.e., close to or less than a boiling point of condensation defects 248), such as less than 50° C., may not cause condensation defects 248 to change states (e.g., from solid phase into gas phase), and heated ion implantation process 270 may not remove (or adequately remove) condensation defects 248. Implantation temperatures that are too high, such as greater than 200° C., may damage etched BARC 228′, which may hinder and/or prevent effective removal thereof. In the depicted embodiment, the implantation temperature is greater than the pre-heat temperature. For example, the implantation temperature may be about 150° C. to about 200° C., and the pre-heat temperature may be about 100° C. to about 150° C. In another example, the implantation temperature may be about 110° C. to about 130° C., and the pre-heat temperature may be about 140° C. to about 160° C. In some embodiments, the implantation temperature and the pre-heat temperature are the same. In some embodiments, the implantation temperature is less than the pre-heat temperature. The present disclosure contemplates other implantation temperatures depending on type of condensation defect and corresponding boiling point, composition of etched middle layer 224′, composition of etched bottom layer 222′, composition of workpiece 200, or a combination thereof.

Parameters of heated ion implantation process 270 (e.g., implant energy, implant angle (e.g., tilt angle and/or twist angle), implant energy, dopant species, dopant source gas, implant dose, etc.) may be tuned to achieve desired doping of exposed portions of substrate 210 (and/or intermediate layer 215) and/or maximize removal of condensation defects 248, such as SO₃₍ₛ₎. In some embodiments, a tilt angle of heated ion implantation process 270 is about 0° to about 80°. For example, heated ion implantation process 270 may be a substantially vertical implant, and an ion beam may be directed at an angle normal to a surface of workpiece 200 (i.e., perpendicular thereto with a tilt angle of about) 0°. In another example, heated ion implantation process 270 is a tilted implantation, and an ion beam may be directed to a surface of workpiece 200 with a tilt angle that is less than about 80°. In some embodiments, heated ion implantation process 270 directs an ion beam to a surface of workpiece 200 with a twist angle that is about 0° to about 360°. In some embodiments, an ion implant energy is about 0.5 kiloelectron volts (keV) to about 600 keV. In some embodiments, an ion implant dose is about 2×10¹⁴ ions/cm² (cm⁻²) to about 4×10¹⁴ cm⁻². In some embodiments, heated ion implantation process 270 is performed by a medium-current ion implanter and/or a high-current ion implanter. In some embodiments, heated ion implantation process 270 is performed by a medium-current ion implanter to form source/drain regions in substrate 210 and/or intermediate layer 215 (i.e., implanted regions 280 are source/drain regions). In some embodiments, heated ion implantation process 270 is performed by a high-current ion implanter to form deep wells in substrate 210 and/or intermediate layer 215 (e.g., implanted regions 280 are n-wells and/or p-wells). In some embodiments, heated ion implantation process 270 includes exhausting condensation defects 248 in their gas state from a process chamber containing workpiece 200. In some embodiments, heated ion implantation process 270 includes performing a purging process that removes condensation defects 248 in their gas state from a process chamber containing workpiece 200.

Heated ion implantation process 270 uses etched BARC 228′ as an implant mask, such that implanted regions 280 are formed in portions of substrate 210 and/or intermediate layer 215 exposed by openings 245 in etched BARC 228′, but not in portions of substrate 210 and/or intermediate layer 215 covered by etched BARC 228′. In some embodiments, implanted regions 280 have a dopant concentration of dopant species that is about 5×10¹⁶ atoms/cm³ (cm⁻³) to about 1×10²¹ cm⁻³. In some embodiments, a dopant concentration of dopant species of exposed, implanted regions 280 of substrate 210 and/or intermediate layer 215 is greater than a dopant concentration of dopant species of unexposed, nonimplanted regions of substrate 210 and/or intermediate layer 215. In some embodiments, a conductivity of exposed, implanted regions 280 of substrate 210 and/or intermediate layer 215 is greater than a conductivity of unexposed, nonimplanted regions of substrate 210 and/or intermediate layer 215, such as where substrate 210 and/or intermediate layer 215 are doped with a semiconductor dopant species (e.g., Si, As, P, B, In, Ge, etc.). In some embodiments, implanted regions 280 are doped regions that include n-type dopant and/or p-type dopant. The n-type dopant may include phosphorus, arsenic, other n-type dopant, or a combination thereof, and the p-type dopant may include boron, indium, other p-type dopant, or a combination thereof. In some embodiments, implanted regions 280 are source/drain regions of a transistor, such as LDD regions and/or HDD regions. The source/drain regions may be doped with n-type dopant and/or p-type dopant. In some embodiments, implanted regions 280 are doped wells, which may define active regions of a device, over which electrically active devices, such as transistors, may be formed. The doped wells may be n-wells (i.e., doped with n-type dopant) and/or p-wells (i.e., doped with p-type dopant).

Since the hot ion implantation process (i.e., pre-heat process 260 and heated ion implantation process 270) removes and/or eliminates residual gas and/or condensation defects 248 on etched BARC 228′ and/or within openings 245 of etched BARC 228′, the hot ion implantation process improves implant dose uniformity, which improves device performance. Implementing pre-heat process 260 may increase and/or improve throughput of implantation processes and/or doping processes. For example, where a subsequent process on a workpiece is performed at an elevated temperature, pre-heat process 260 and the subsequent process may be performed in separate process chambers, such that pre-heat process 260 may heat the workpiece and/or features thereof to a pre-heat temperature, which reduces a time needed by the subsequent process to heat the workpiece and/or features thereof to a desired process temperature, which may be the same or greater than the pre-heat temperature. In some embodiments, pre-heat process 260 is performed in a first process chamber, heated ion implantation process 270 is performed in a second process chamber, and workpiece 200 is transferred from the first process chamber to the second process chamber. Heating workpiece 200 and/or features thereof to the pre-heat temperature in the first process chamber may reduce a time needed to heat workpiece 200 and/or features thereof to the implantation temperature and/or reduce a time between etching process 240 and heated ion implantation process 270 (i.e., Q-time may be reduced). Further, since the hot ion implantation process can completely remove residual gas and/or condensation defects 248 from high aspect ratio BARC patterns, condensation defects 248 may be removed without performing a DI water rinse, which is known to cause BARC pattern collapse.

In some embodiments, method 100 may include configuring a dechucking process to further reduce and/or remove residual gas and/or condensation defects 248. For example, workpiece 200 (e.g., substrate 210 thereof) may be secured to a chuck during processing, such as during etching process 240, during pre-heat process 260, during heated ion implantation process 270, or a combination thereof. Method 100 may further include dechucking workpiece 200 from a chuck and flowing a dechucking gas into a process chamber while dechucking workpiece 200. The dechucking gas includes carbon monoxide (CO) gas, in addition, to argon (Ar) gas, to reduce residual gas and/or condensation defects. For example, CO may react with condensation defects 248, causing condensation defects 248 to transition from solid state (e.g., SO₃₍ₛ₎ to gas state (e.g., SO_{3(g)}). In some embodiments, chemical reactions may occur with CO that produce SO_{3(g)}, such as SO₃₍ₛ₎+CO_{(g)}→SO_{2(g)}+CO_{2(g)}. In some embodiments, the dechucking process includes exhausting condensation defects 248 in their gas state from the process chamber. In some embodiments, the dechucking process includes performing a purging process that removes condensation defects 248 in their gas state from the process chamber. Workpiece 200 is exposed to the dechucking gas after etching process 240, before pre-heat process 260, after pre-heat process 260, before heated ion implantation process 270, after heated ion implantation process 270, other suitable time for reducing condensation defects, or a combination thereof.

Referring to FIG. 1 and FIG. 2F, method 100 at block 135 includes removing etched middle layer 224′ and etched bottom layer 222′ (i.e., etched BARC 228′). Etched middle layer 224′ and etched bottom layer 222′ may be removed by a suitable process, leaving patterned workpiece 200 (e.g., having implanted regions 280 therein). For example, etched BARC 228′ is removed by a resist stripping process. The resist stripping process may be a wet strip and/or a plasma ashing. In another example, etched BARC 228′ is removed by an etching process, which may selectively remove BARC 228′ with respect to substrate 210 and/or intermediate layer 215. In some embodiments, etched middle layer 224′ and etched bottom layer 222′ are removed by separate processes, such as separate resist stripping processes or separate etching processes. In some embodiments, etched middle layer 224′ and etched bottom layer 222′ are removed by the same process. In some embodiments, a cleaning process may be performed after removing etched BARC 228′ to remove any resist residue from workpiece 200.

Variations of method 100 are contemplated by the present disclosure. For example, in some embodiments, etching process 240 may include a first etch step that selectively removes middle layer 224 with respect to patterned top layer 226′ and/or bottom layer 222 and a second etch step that selectively removes bottom layer 222 with respect to etched middle layer 224′ and/or an underlying layer (e.g., intermediate layer 215 and/or substrate 210). In some embodiments, patterned top layer 226′ may be partially or completely removed during the first etch step, and etched middle layer 224′ may be partially or completely removed during the second etch step. In some embodiments, etched middle layer 224′ is removed before the hot ion implantation process, and etched bottom layer 222′ alone functions as the implant mask. In such embodiments, etched bottom layer 222′ may be removed after the hot ion implantation process. In some embodiments, the implant mask may be formed by patterning and/or etching any number of patterning layers. In other words, the condensation reduction and removal techniques described herein are not limited to patterns formed from tri-layer patterning stacks. Further, in some embodiments, etched BARC 228′ or portions thereof, may function as an etch mask, and instead of performing heated ion implantation process 270, method 100 may include performing an etching process to form trenches in substrate 210, openings in intermediate layer 215, openings in a material layer of workpiece 200 (which may form a portion of substrate 210), or a combination thereof. In such embodiments, residual gas and/or condensation defects 248 may be reduced and/or removed by pre-heat process 260, reducing O₂ when etching BARC 228, exposing condensation defects 248 to a dechuck gas that includes CO when dechucking workpiece 200, or a combination thereof, such as described herein.

Depending on fabrication stage of workpiece 200, method 100 and/or portions thereof may be performed on any base material on which processing is conducted to provide a patterned material layer that may form a portion of a semiconductor device, such as a transistor, or that may be used to form a semiconductor device. In some embodiments, substrate 210 may include various material layers (e.g., dielectric layers, semiconductor layers, metal layers, or a combination thereof) configured and combined to form device features (e.g., n-wells, p-wells, isolation structures, source/drains, gates, gate spacers, source/drain contacts, gate contacts, vias, metal lines, other device features, or a combination thereof). In such embodiments, method 100 may be performed on a material layer of substrate 210, such that implantation regions 280 are formed in the material layer. In some embodiments, the material layer is a semiconductor layer including, for example, silicon, germanium, silicon germanium, other suitable semiconductor constituent, or a combination thereof. In some embodiments, the material layer is a metal layer including, for example, titanium, aluminum, tungsten, tantalum, copper, cobalt, ruthenium, alloys thereof, other suitable metal constituent and/or alloys thereof, or a combination thereof. In some embodiments, the material layer is a dielectric layer including, for example, silicon and/or metal in combination with oxygen, nitrogen, carbon, other suitable dielectric constituent, or a combination thereof. In some embodiments, the material layer is a hard mask layer to be patterned for use in subsequent processing of workpiece 200 (e.g., where BARC 228′ may be implemented as an etch mask to pattern the hard mask layer and heated ion implantation process may be omitted). In some embodiments, the material layer forms a gate feature (e.g., a gate dielectric and/or a gate electrode), a source/drain (e.g., an epitaxial source/drain), or an interconnect feature (e.g., an electrically conductive structure or a dielectric layer of a multilayer interconnect). In some embodiments, where workpiece 200 is fabricated into a mask for patterning layers when fabricating semiconductor devices, substrate 210 may be a mask substrate that includes a transparent material and/or a low thermal expansion material (e.g., glass, quartz, silicon oxide titanium, and/or other suitable material), and method 100 and/or portions thereof may be performed thereon to pattern substrate 210 and/or a material layer thereof, such as an absorber layer (for example, the material layer may be a chromium layer).

Workpiece 200 may be a portion of an IC chip, a system on chip (SoC), or portion thereof, that includes various passive and active microelectronic devices, such as resistors, capacitors, inductors, diodes, p-type FETs (PFETs), n-type FETs (NFETs), metal-oxide semiconductor FETs (MOSFETs), complementary metal-oxide semiconductor (CMOS) transistors, bipolar junction transistors (BJTs), laterally diffused MOS (LDMOS) transistors, high voltage transistors, high frequency transistors, other components, or a combination thereof. Accordingly, implanted regions 280 may form a portion of variety of devices. In some embodiments, implanted regions 280 form a portion of a planar transistor. In some embodiments, implanted regions 280 form a portion a multigate transistor, such as a fin-like field transistor (FinFET), a gate-all-around (GAA) transistor, a fork-sheet transistor, an omega-gate (Ω-gate) device, a pi-gate (Π-gate) device, other type of multigate transistors, or a combination thereof. The planar transistor and/or the multigate transistor may be a MOSFET, in some embodiments. In some embodiments, implanted regions 280 form a portion of a logic device. In some embodiments, implanted regions 280 form a portion of a memory device.

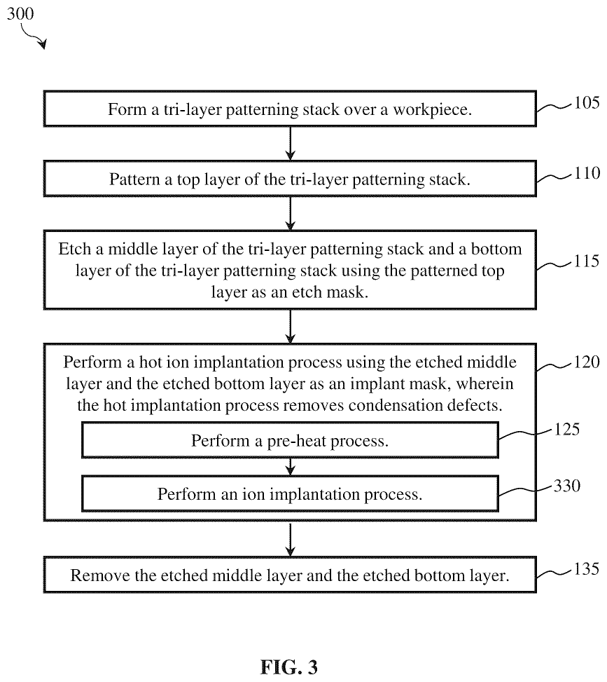

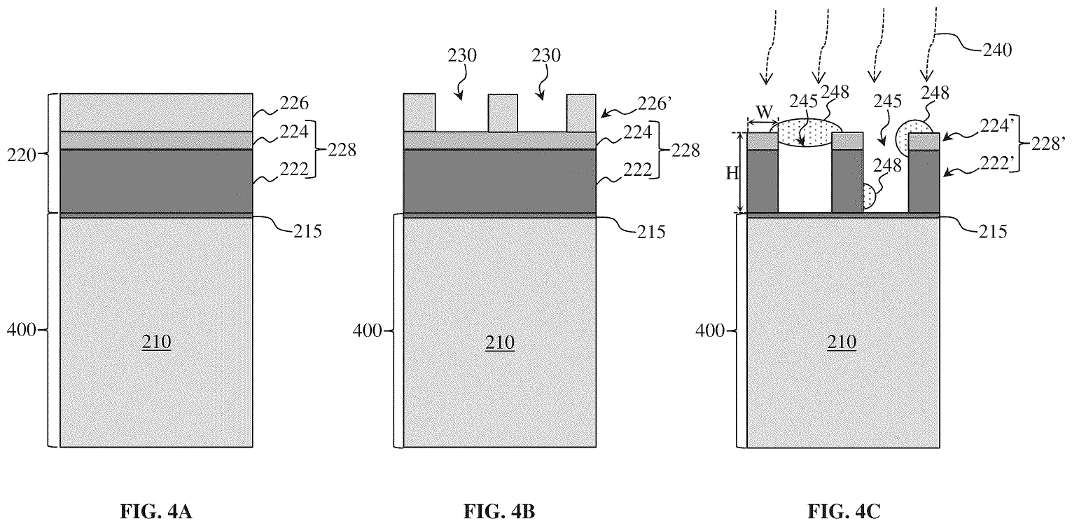

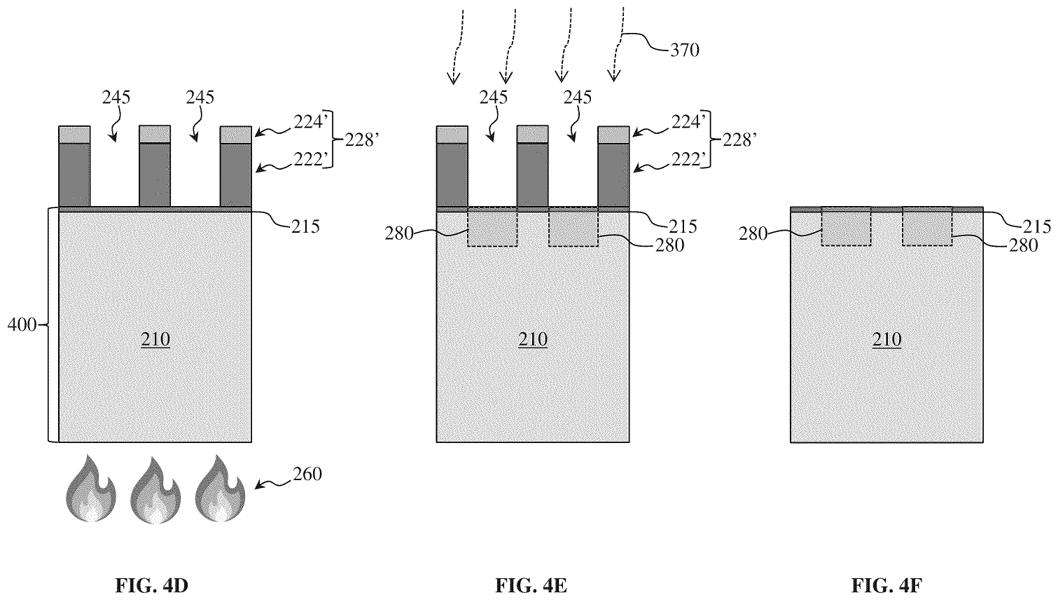

In some embodiments, such as depicted and described with reference to FIG. 3 and FIGS. 4A-4F, pre-heat process 260 at block 125 may sufficiently remove residual gas and condensation defects, such that it is unnecessary to ensure that an implantation temperature is greater than a boiling point of residual gas and/or condensation defects. FIG. 3 is a flow chart of a method 300, in portion or entirety, for patterning a workpiece that reduces and/or removes condensation defects, according to various aspects of the present disclosure. FIGS. 4A-4F are cross-sectional views of a workpiece 400, in portion or entirety, at various stages of method 300 of FIG. 3, according to various aspects of the present disclosure. FIG. 3 and FIGS. 4A-4F are discussed concurrently herein for ease of description and understanding. FIG. 3 and FIGS. 4A-4F have been simplified for the sake of clarity to better understand the inventive concepts of the present disclosure. Method 300 and workpiece 400 are similar to method 100 and workpiece 200, such as described above with reference to FIG. 1 and FIGS. 2A-2F. Accordingly, similar features are identified by the same reference numerals for clarity and simplicity. Additional steps can be provided before, during, and after method 300, and some of the steps described can be moved, replaced, or eliminated for additional embodiments of method 300. Additional features may be added in workpiece 400, and some of the features described below can be replaced, modified, or eliminated in other embodiments of workpiece 400.

In FIG. 3, method 300 includes forming a tri-layer patterning stack (e.g., tri-layer patterning stack 220) over a workpiece (e.g., workpiece 400) at block 105 (FIG. 4A), patterning a top layer (e.g., top layer 226) of the tri-layer patterning stack at block 110 (FIG. 4B), etching a middle layer (e.g., middle layer 224) of the tri-layer patterning stack and a bottom layer (e.g., bottom layer 222) of the tri-layer patterning stack using the patterned top layer as an etch mask at block 115 (FIG. 4C), and performing a hot ion implantation process using the etched middle layer and the etched bottom layer as an implant mask (FIG. 4D and FIG. 4E). In contrast to the hot ion implantation process at block 120 of method 100, the hot ion implantation process at block 120 of method 300 includes performing a pre-heat process (e.g., pre-heat process 260) at block 125 (FIG. 4D) and performing an ion implantation process (e.g., an ion implantation process 370) at block 330 (FIG. 4E). In method 300, because pre-heat process 260 sufficiently removes condensation defects 248, implantation parameters of ion implantation process 370 do not account for removing condensation defects 248. For example, an implantation temperature of ion implantation process 370 is not specifically tuned/configured greater than a boiling point of condensation defects 248. The implantation temperature of ion implantation process 370 at block 330 may thus not be greater than a boiling point of condensation defects 248. In some embodiments, ion implantation process 370 may include heating workpiece 400 (e.g., substrate 210 thereof), heating an environment of workpiece 400 (e.g., ambient temperature of a process chamber), heating etched BARC 228′ (e.g., etched middle layer 224′ and/or etched bottom layer 222′), or a combination thereof to an implantation temperature, and the implantation temperature may be less than, the same as, or greater than the boiling point of condensation defects 248. Since ion implantation process 370 is not specifically tuned to have an implantation temperature greater than a boiling point of condensation defects 248, ion implantation process 370 is not referred to as a “heated” ion implantation process. Method 300 may then proceed with removing the etched middle layer and the etched bottom layer at block 135 (FIG. 4F).

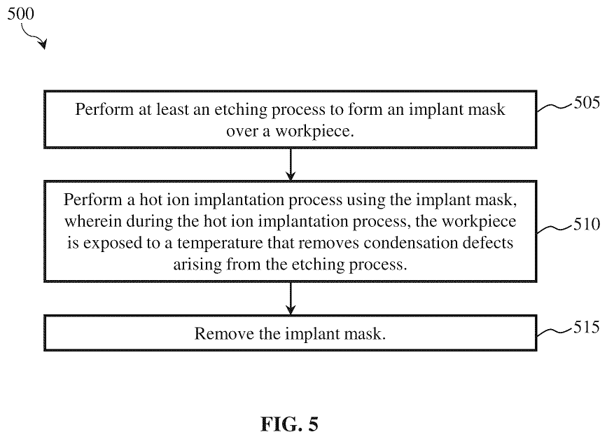

The present disclosure contemplates various embodiments of a hot ion implantation process for removing residual gas and/or condensation defects that arise when forming an implant mask, thereby improving patterning (e.g., implant) uniformity. FIG. 5 is a flow chart of a method 500, in portion or entirety, for patterning a workpiece that reduces and/or removes condensation defects, according to various aspects of the present disclosure. Method 500 at block 505 includes performing at least an etching process to form an implant mask over a workpiece. The implant mask may be a single layer or a multilayer patterning stack, such as tri-layer patterning stack 220. The etching process expose the workpiece to an etch gas that includes tetrafluoromethane (CF₄), oxygen (O₂), carbonyl sulfide (COS), or a combination thereof. The etching process may be a single etch or a multistep etch. Method 500 at block 510 includes performing a hot ion implantation process using the implant mask. During the hot ion implantation process, the workpiece is exposed to a temperature that removes condensation defects (e.g., SO₃ defects) that arise during the etching process. The temperature is greater than a boiling point of the condensation defects. In some embodiments, the hot ion implantation process includes a pre-heat process and an ion implantation process, and the workpiece is exposed to the temperature that removes the condensation defects during the pre-heat process. The workpiece may also be exposed to the temperature that removes the condensation defects during the implantation process. In some embodiments, the workpiece (e.g., a substrate thereof) is elevated to the temperature that removes the condensation defects. In some embodiments, the hot ion implantation process may not include the pre-heat process, and the hot implantation process exposes the workpiece to an implant temperature that removes the condensation defects. The hot ion implantation process may form implant regions in the workpiece. Method 500 at block 515 includes removing the implant mask. FIG. 5 has been simplified for the sake of clarity to better understand the inventive concepts of the present disclosure. Additional steps can be provided before, during, and after method 500, and some of the steps described can be moved, replaced, or eliminated for additional embodiments of method 500.

The present disclosure provides for many different embodiments. An exemplary method includes forming a tri-layer patterning stack over a workpiece. The tri-layer patterning stack includes a bottom layer disposed over the workpiece, a middle layer disposed over the bottom layer, and a top layer disposed over the middle layer. The method further includes, after performing a lithography process and an etching process on the tri-layer patterning stack, performing a hot ion implantation process to form implanted regions in the workpiece. The hot ion implantation process removes condensation defects.

In some embodiments, performing the hot ion implantation process to form the implanted regions in the workpiece includes performing a pre-heat process, performing a heated ion implantation process, and tuning pre-heat process parameters and heated ion implantation process parameters to remove the condensation defects. The pre-heat process parameters include a pre-heat temperature, the heated ion implantation process parameters include an implantation temperature, and each of the pre-heat temperature and the implantation temperature is greater than a boiling point of the condensation defects. In some embodiments, the pre-heat temperature is about 50° C. to about 200° C., the implantation temperature is about 50° C. to about 200° C., and the implantation temperature is greater than the pre-heat temperature. In some embodiments, the pre-heat process is performed in a first process chamber and the heated ion implantation process is performed in a second process chamber different than the first process chamber.

In some embodiments, the etching process exposes the tri-layer patterning stack to an etch gas that includes tetrafluoromethane (CF₄), oxygen (O₂), and carbonyl sulfide (COS). In such embodiments, the condensation defects may be SO₃ defects. In some embodiments, the method includes performing a dechucking process, and parameters of the dechucking process are tuned to remove the condensation defects. In some embodiments, the etching process includes performing a first etch and a second etch on the bottom layer of the tri-layer patterning stack. The first etch may implements a first O₂+COS etch gas having a first O₂ concentration, and the second etch may implement a second O₂+COS etch gas having a second O₂ concentration. The second O₂ concentration is less than the first O₂ concentration.

In some embodiments, the top layer is a photosensitive layer, the middle layer is a first bottom antireflective layer, and the bottom layer is a second bottom antireflective layer. The lithography process may be performed on the top layer of the tri-layer patterning stack, and the lithography process may provide a patterned top layer. The etching process may be performed on the middle layer of the tri-layer patterning stack and the bottom layer of the tri-layer patterning stack, and the etching process may provide a patterned antireflective coating. The etching process uses the patterned top layer as an etch mask. In some embodiments, the hot ion implantation process uses the patterned antireflective coating as an implant mask.

Another exemplary method includes forming a tri-layer patterning stack over a workpiece, patterning a top layer of the tri-layer patterning stack, etching a middle layer of the tri-layer patterning stack, and etching a bottom layer of the tri-layer patterning stack. The middle layer and/or the bottom layer may be etched using the patterned top layer as an etch mask. The method further includes performing a hot ion implantation process to form implanted regions in the workpiece. The hot ion implantation process uses the etched middle layer and/or the etched bottom layer as an implant mask. The hot ion implantation process removes residual gas and/or condensation defects, which may be on and/or within openings of the etched middle layer and/or the etched bottom layer. The method further includes removing the etched middle layer and removing the etched bottom layer. In some embodiments, the etched middle layer is removed before performing the hot ion implantation process, and the etched bottom layer is removed after performing the hot ion implantation process. In some embodiments, the etched middle layer and the etched bottom layer are removed after performing the hot ion implantation process.

In some embodiments, the hot ion implantation process includes a pre-heating phase and a heated ion implantation phase. Each of a pre-heat temperature of the pre-heating phase and an implantation temperature of the heated ion implantation phase is greater than a boiling point of the condensation defects. In some embodiments, the implantation temperature of the heated ion implantation phase is greater than the pre-heat temperature of the pre-heating phase. In some embodiments, method includes dechucking the workpiece from a chuck to which it is secured and flowing a dechucking gas into a process chamber when dechucking the workpiece from the chuck. The dechucking gas includes carbon (C), oxygen (O), and argon (Ar). In some embodiments, the dechucking gas includes CO gas and Ar gas, and the CO gas causes the condensation defects to transition from a solid state to a gas state.

In some embodiments, etching the middle layer of the tri-layer patterning stack includes performing a first dry etch and etching the bottom layer of the tri-layer patterning stack includes performing a second dry etch. The first dry etch implements a fluorine-containing etch gas, and the second dry etch implements an oxygen-containing etch gas. In some embodiments, the fluorine-containing etch gas includes CF₄, the oxygen-containing etch gas includes O₂ and COS, formation of the condensation defects is caused by residual oxygen-containing etch gas, and the condensation defects include SO₃₍ₛ₎. In some embodiments, performing the hot ion implantation process includes tuning parameters of the hot ion implantation process to cause SO₃₍ₛ₎ to become SO_{3(g)}. In some embodiments, the method further includes reducing a concentration of O₂ in the oxygen-containing etch gas during the second dry etch.

Yet another exemplary method includes forming a tri-layer patterning stack over a substrate. The tri-layer patterning stack includes a bottom layer disposed over the substrate, a middle layer disposed over the bottom layer, and a top layer disposed over the middle layer. The method further includes forming an etch mask by patterning the top layer of the tri-layer patterning stack. The method further includes forming an implant mask by performing a first dry etch on the middle layer of the tri-layer patterning stack and a second dry etch on the bottom layer of the tri-layer patterning stack. Each of the first dry etch and the second dry etch use the etch mask. The method further includes performing a hot ion implantation process to form implanted regions in the substrate. The hot ion implantation process uses the implant mask. A temperature of the hot ion implantation process is greater than a boiling point of condensation defects on the implant mask to cause the condensation defects to transition from a solid state to a gas state. The method further includes removing the implant mask.

In some embodiments, the first dry etch is a CF₄ plasma etch. In some embodiments, the second dry etch is an O₂+COS plasma etch. In some embodiments, the condensation defects in the solid state are SO₃₍ₛ₎, and the condensation defects in the gas state are SO_{3(g)}. In some embodiments, forming the tri-layer patterning stack over the substrate includes forming a carbon-rich polymer layer over the substrate, forming a silicon-rich polymer layer over the carbon-rich polymer layer, and forming a photosensitive layer over the silicon-rich polymer layer. The carbon-rich polymer layer provides the bottom layer, the silicon-rich polymer layer provides the middle layer, and the photosensitive layer provides the top layer.

Yet another exemplary method includes forming a patterning layer over a material layer, performing a dry etch on the patterning layer to form openings in the patterning layer that expose portions of the material layer, performing a pre-heat process to remove condensation defects from the patterning layer and/or from within the openings of the patterning layer, and patterning the exposed portions of the material layer using the etched patterning layer as a patterning mask. In some embodiments, parameters of the pre-heat process are tuned to cause the condensation defects to transition from a solid state to a gas state. In some embodiments, the condensation defects are removed without performing a rinsing process, such as a DI water rinse. In some embodiments, the patterning includes doping the exposed portions of the material layer. In some embodiments, the patterning includes etching the exposed portions of the material layer. In some embodiments, the dry etch implements an O₂+COS, and the method further includes decreasing O₂ from a first amount to a second amount during the dry etch to remove the condensation defects. In some embodiments, the method further includes exposing the patterning layer to a CO+Ar dechucking gas to reduce the condensation defects.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a high aspect ratio pattern structure over a device structure, wherein the high aspect ratio pattern structure has a ratio of a height to a width that is at least 5 and the forming the high aspect ratio pattern structure includes performing a dry etch that implements an etchant that includes carbon, sulfur and oxygen; and
implanting dopant species into the device structure using the high aspect ratio pattern structure as an implant mask, wherein an implant temperature is greater than a boiling point of condensation defects resulting from the dry etch.

2. The method of claim 1, wherein the forming the high aspect ratio pattern structure includes forming a patterned layer of a hydrophobic material.

3. The method of claim 2, wherein the forming the patterned layer of the hydrophobic material includes forming a patterned amorphous carbon layer.

4. The method of claim 2, wherein the patterned layer of the hydrophobic material is a first patterned layer and the forming the high aspect ratio pattern structure further includes forming a second patterned layer of a silicon-rich polymer material over the first patterned layer.

5. The method of claim 1, further comprising storing the device structure in an environment with at least 30% humidity at room temperature after forming the high aspect ratio pattern structure and before implanting the dopant species into the device structure.

6. The method of claim 5, further comprising storing the device structure in the environment with at least 30% humidity at room temperature about an hour or less.

7. The method of claim 1, wherein:
the performing the dry etch includes a first dry etch and a second dry etch;
the etchant includes a first etchant and a second etchant, wherein the first dry etch implements the first etchant and the second dry etch implements the second etchant;
the first etchant includes tetrafluoromethane (CF₄); and
the second etchant includes carbonyl sulfide (COS) and diatomic oxygen (O₂).

8. The method of claim 7, further comprising implementing a first concentration of diatomic oxygen and a second concentration of diatomic oxygen during the second dry etch, wherein the first concentration of diatomic oxygen is greater than the second concentration of diatomic oxygen and the first concentration of diatomic oxygen is implemented before the second concentration of diatomic oxygen.

9. The method of claim 1, wherein the implant temperature is at least 50° C.

10. The method of claim 1, further comprising performing a dechucking process that exposes the high aspect ratio pattern structure to a carbon monoxide gas.

11. The method of claim 1, wherein the condensation defects are removed without exposing the high aspect ratio pattern structure to a deionized water rinse.

12. A method comprising:
forming a first patterning layer of a first composition;
forming a second patterning layer of a second composition over the first patterning layer, wherein the second composition is different from the first composition;
forming a third patterning layer of a third composition over the second patterning layer, wherein the third composition is different from the second composition;
patterning the third patterning layer to expose the second patterning layer;
etching the second patterning layer to expose the first patterning layer;
etching the first patterning layer to expose an underlying layer; and
implanting dopant species into the exposed underlying layer, wherein an implant temperature is greater than a boiling point of condensation defects resulting from the etching.

13. The method of claim 12, wherein:
the forming the first patterning layer of the first composition includes forming a first antireflective layer that includes carbon, hydrogen, and oxygen;
the forming the second patterning layer of the second composition includes forming a second antireflective layer that includes silicon, carbon, hydrogen, and oxygen;
the forming the third patterning layer includes forming a photoresist layer that includes a photosensitive component and carbon, hydrogen, oxygen, or a combination thereof;
the etching the second patterning layer includes performing a first dry etch using a first dry etchant that includes carbon and fluorine; and
the etching the first patterning layer includes performing a second dry etch using a second dry etchant that includes carbon, sulfur and oxygen.

14. The method of claim 12, wherein:
the implant temperature includes a first temperature and a second temperature;
the implanting the dopant species into the exposed underlying layer includes performing a heating step using the first temperature and performing an implant step using the second temperature, wherein the heating step is performed before the implant step; and
the method includes configuring the first temperature used during the heating step greater than the boiling point of the condensation defects resulting from the etching.

15. The method of claim 14, further comprising configuring the second temperature used during the implant step greater than the first temperature.

16. The method of claim 15, wherein the boiling point of the condensation defects resulting from the etching is less than about 50° C., the first temperature is about 100° C. to about 150° C., and the second temperature is about 150° C. to about 200° C.

17. The method of claim 12, wherein the implanting dopant species into the exposed underlying layer includes using a medium-current ion implanter to form source/drain regions in the exposed underlying layer.

18. The method of claim 12, wherein the implanting dopant species into the exposed underlying layer includes using a high-current ion implanter to form doped wells in the exposed underlying layer.

19. A method comprising:
forming a bottom antireflective coating (BARC) pattern over a substrate, wherein the BARC pattern has a ratio of a height to a width that is at least 5 and the forming the BARC pattern includes performing a first dry etch and a second dry etch, wherein the BARC pattern is exposed to carbon and fluorine during the first dry etch and the BARC pattern is exposed to carbon, sulfur, and oxygen during the second dry etch; and
performing a hot ion implantation process to form source/drain regions in the substrate, wherein the hot ion implantation process uses the BARC pattern as an implant mask and parameters of the hot ion implantation process are tuned to remove condensation defects resulting from the first dry etch, the second dry etch, or both.

20. The method of claim 19, wherein:
the first dry etch is a CF₄ plasma etch;
the second dry etch is an O₂+COS plasma etch;
the condensation defects are SO₃₍ₛ₎;
a boiling point of the condensation defects is less than 50° C.; and
tuning the parameters of the hot ion implantation process to remove the condensation defects includes tuning a temperature of the hot ion implantation process greater than 50° C.
